(19) United States
(12) Patent Application Publication
(10) Pub. No.: US 2015/0077935 A1
(43) Pub. Date: Mar. 19, 2015

(54) Air Filter And Cable Management Assemblies For Network Communication Systems

(71) Applicant: Anue Systems, Inc., Austin, TX (US)

(72) Inventors: Cary J. Wright, Austin, TX (US); Kevin R. Garrett, Austin, TX (US); Scott D. Slade, Round Rock, TX (US); David E. Howard, Austin, TX (US); Darryl D. Daniel, Austin, TX (US); Christopher C. Ott, Austin, TX (US)

(73) Assignee: Anue Systems, Inc., Austin, TX (US)

(21) Appl. No.: 14/026,219

(22) Filed: Sep. 13, 2013

(51) Int. Cl. H05K 7/20; F16L 3/08

(52) U.S. Cl. CPC H05K 7/20181; F16L 3/08
USPC 361/695; 361/807; 248/65; 454/237; 454/253; 55/385.6

(57) ABSTRACT

Air filter and cable management assemblies for network communication systems are disclosed. The assemblies include filters that cover one or more communication line cards and their associated connection panels. The assemblies also include cable support structures with cable support brackets that support connected cables while restricting airflow so that airflow is forced through the filter towards the connection panels. This airflow can then pass into housings for the line cards and other circuitry, such as fabric cards, to provide desired cooling. Fan subsystems can also be provided to facilitate airflow. Advantageously, the disclosed air filter and cable management assemblies allow for filtered cooling of stacked network communication systems while greatly simplifying the complexity of the filter and cable installation and maintenance.

### TECHNICAL FIELD

This disclosed embodiments relate to cooling of electronic equipment and, more particularly, to air cooling of network communication systems.

### BACKGROUND

Cooling is required for many network communication systems and is particularly important when many network communication systems are placed in close proximity to each other. One environment in which this need for cooling exists is within central telecommunication hubs, which often conform to NEBS (Network Equipment-Building System) guidelines. In such environments, air cooling is often utilized to dissipate heat from electrical components within the network communication systems. In addition to this air cooling, filtering of airborne particulates within the airflow is often desirable to avoid build-up of dust particles within a system. A build-up of dust particles can lead to poor airflow, overheating, and increased fire risks.

FIG. 1 (Prior Art) is a block diagram of an example embodiment 100 where network communication systems have been organized according to NEBS guidelines. As shown, communication equipment racks 102, 106, and 110 hold network communication systems 104, 108, and 112, respectively. Typically, each rack will be configured to hold ten or more closely-spaced and stacked network communication systems, and each row will typically include multiple racks. As such, considerable heat can be generated in a relatively confined space when these racks are fully populated with network communication systems.

To provide heat dissipation in many such environments, cooled air is forced up through the bottom of the racks 102, 106, and 110 and vented out the top of the racks 102, 106, and 110. This airflow provides for cooling of the systems mounted within the racks. Alternatively, cold aisles 130/132 and hot aisles 134/136 can be formed between the rows of network communication systems. The cold aisles 130 and 132 receive cooled air as indicated by arrows 120 and 122. As shown by arrows 140, 142, and 144, the airflow passes through the network communication systems 104, 108, and 112 to provide heat dissipation for these network communication systems. The resulting heated air then flows into the hot aisles 134 and 136. These hot aisles 134/136 provide the air return path for the air cooling process as shown by arrows 124 and 126.

FIG. 2 (Prior Art) is a block diagram of an example embodiment for network communication system 104. For the embodiment depicted, the network communication system 104 includes a connection panel 202, a cover plate 204, a shaped filter 206, an electronics compartment 210, and fans 208. The connection panel 202 includes a number of connection ports for communication cables, such as Ethernet and/or other communication cables (e.g., CAT5, CAT6 rated cabling). The cover plate 204 is perforated to allow air to flow through the cover plate 204 and into the compartment 210. The filter 206 is shaped to fit around the connection panel 202 and to match the shape of the perforated cover plate 204. The compartment 210 includes the electrical circuitry and components for which cooling is needed. The fans 208 are utilized to help force the airflow 140 into and through the compartment 210. As shown in FIG. 1A (Prior Art), the airflow 140 will enter from the cold aisle 130 and exit into the hot aisle 134, and the outgoing air will have been heated through a heat exchange process between the cooled air entering the system 104 and the hot electrical circuitry and components within compartment 210.

Difficulties arise, however, with the air cooling solution described above. One difficulty is that the shaped filters and cover plates lead to undesirable complexity, as different network communication systems are often included within a rack with each different system often having a different connection panel configuration. As such, different shaped filters are required for each different system. Further, access is required to the front of each communication system in order to remove the cover plate 204 and replace the shaped filter 206 on each system when it has reached the end of its useful life. As communication cables will typically be attached to the connection panel 202, the process of replacing the shaped filter 206 is difficult and time consuming, as the cabling must often be removed prior to filter replacement. Further, due to this difficulty, technicians tend to avoid replacing filters, which can then become clogged and restrict airflow into the communication systems. The restricted airflow reduces cooling efficiency and can ultimately lead to equipment failures.

### SUMMARY OF THE DISCLOSED EMBODIMENTS

Air filter and cable management assemblies for network communication systems are disclosed. The assemblies include filters that cover one or more communication line cards and their associated connection panels. The assemblies also include cable support structures with cable support brackets that support connected cables while restricting airflow so that airflow is forced through filters towards the connection panels. This airflow can then pass into housings for the line cards and other circuitry, such as fabric cards, to provide desired cooling. Fan subsystems can also be provided to facilitate airflow. Advantageously, the disclosed air filter and cable management assemblies allow for filtered cooling of stacked network communication systems while greatly simplifying the complexity of the filter and cable installation and maintenance. Other features and variations can be implemented, and related systems and methods can be utilized, as well.

Embodiments are disclosed for a network communication system including a connection panel frame having a front surface, at least one communication system coupled to the connection panel frame and having a connection panel accessible from the front surface of the connection panel frame, and a filter and cable management assembly coupled to the connection panel frame. The assembly further includes a cable support structure having at least one cable support bracket positioned along a vertical edge of the connection panel frame and being configured to restrict airflow and to receive communication cables associated with the connection panel, a filter positioned over the connection panel, and a filter housing positioned over the filter to hold the filter in a secured relationship with respect to the cable support structure and the connection panel frame.

In further embodiments, a plurality of communication systems are coupled to the connection panel frame, and each of the communication systems has a connection panel accessible from the front surface of the connection panel frame. In addition, at least one cable support bracket can be provided for each connection panel. For other embodiments, the cable support structure can include a first cable support structure having a plurality of cable support brackets positioned along a first vertical edge of the connection panel frame and a second cable support structure having a plurality of cable support brackets positioned along a second vertical edge of the connection panel frame. Further, the communication systems can include a plurality of communication line cards coupled to the connection panel frame and a plurality of fabric cards coupled to the communication line cards. Still further, the system can include a housing including the connection panel frame and holding the line cards and the fabric cards. Also, the system can further include a fan subsystem coupled within the housing. The filter can include a filter frame holding filter media, and the filter media can include a porous filter material.

In still further embodiments, the cable support brackets comprise a support body having a void and a gasket positioned within the void. In addition, the gasket can include a foam material, and the foam material can be polyurethane foam. Further, the gasket can be implemented as multiple pieces or as a single piece. Still further, at least a portion of the gasket can be folded to position the gasket within the void. Also, the cable support bracket can be shaped to facilitate insertion of cables into the cable support bracket.

Embodiments are also disclosed for a filter and cable management assembly including a cable support structure having at least one cable support bracket configured to be positioned along a first vertical edge of a connection panel frame for at least one communication system having a connection panel and to restrict airflow and to receive communication cables associated with the connection panel, a filter, and a filter housing positioned to hold the filter in a secured relationship with respect to the cable support structure and the connection panel frame.

In further embodiments, the cable support structure can include a first cable support structure having a plurality of cable support brackets configured to be positioned along a first vertical edge of the connection panel frame and a second cable support structure having a plurality of cable support brackets configured to be positioned along a second vertical edge of the connection panel frame. In addition, the filter can include a filter frame holding filter media, and the filter media can be a porous filter material. Further, the cable support bracket can include a support body having a void and a gasket positioned within the void. Still further, the gasket can include a foam material, and the foam material can be a polyurethane foam. Also, the cable support brackets can be shaped to facilitate insertion of cables into the cable support brackets.

Further embodiments are disclosed for a method for controlling airflow for a network communication system including receiving airflow for a network communication system through a filter and cable management system and exhausting the airflow from the communication system. The filter and cable management system includes a cable support structure, a filter, and a filter housing. The cable support structure includes at least one cable support bracket positioned along a first vertical edge of a connection panel frame for at least one communication system having a connection panel where the cable support bracket restricts airflow and receives communication cables associated with the connection panel. And the filter housing is positioned to hold the filter in a secured relationship with respect to the cable support structure and the connection panel frame.

In further embodiments, a plurality of communication systems are coupled to the connection panel frame with each of the communication systems having a connection panel accessible from the front surface of the connection panel frame. In addition, the cable support structure can include a first cable support structure having a plurality of cable support brackets positioned along a first vertical edge of the connection panel frame and a second cable support structure having a plurality of cable support brackets positioned along a second vertical edge of the connection panel frame. Further, the communication system can include a plurality of communication line cards coupled to the connection panel frame and a plurality of fabric cards coupled to the communication line cards. Still further, the exhausting step can be performed using a fan subsystem. Also, the cable support bracket can include a support body having a void and a gasket positioned within the void.

Additional and/or different features and embodiments can be also implemented, as desired, and related systems and methods can be utilized, as well.

### DESCRIPTION OF THE DRAWINGS

It is noted that the appended drawings illustrate only exemplary embodiments and are, therefore, not to be considered limiting of the scope of the invention, for the invention may admit to other equally effective embodiments.

FIG. 1 (Prior Art) is a block diagram of an example embodiment for network communication systems within rows of equipment racks.

FIG. 2 (Prior Art) is a block diagram of an example embodiment for a network communication system having a shaped filter.

FIG. 3 is a block diagram of an embodiment for a network communication system having an airflow and cable management assembly.

FIG. 4. is an expanded view diagram of a more detailed example embodiment for a filter and cable management assembly that can be used with stacked network communication systems.

FIG. 5 is a top view diagram of an embodiment showing cable connections exiting through a cable support bracket.

FIG. 6 is a collapsed view diagram showing an embodiment for a closed filter and cable management assembly.

FIG. 7A is an exploded view diagram of an example embodiment for a cable support bracket.

FIG. 7B is a collapsed view of the cable support bracket with an inserted gasket.

FIG. 8A is a diagram of an embodiment where a single cable has been inserted into a cable support bracket.

FIG. 8B is a diagram of an embodiment where multiple cables have been inserted into a cable support bracket.

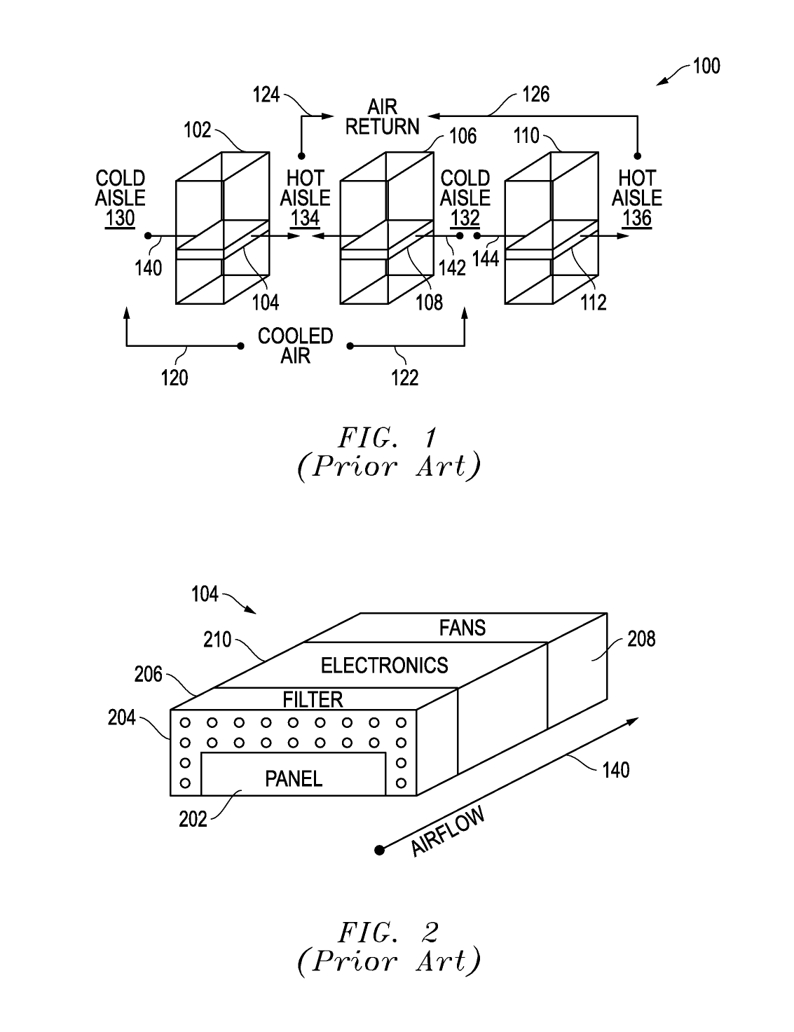

### DETAILED DESCRIPTION

Air filter and cable management assemblies for network communication systems are disclosed. The assemblies include filters that cover one or more communication line cards and their associated connection panels. The assemblies also include cable support structures with cable support brackets that support connected cables while restricting airflow so that airflow is forced through filters towards the connection panels. This airflow can then pass into housings for the line cards and other circuitry, such as fabric cards, to provide desired cooling. Fan subsystems can also be provided to facilitate airflow. Advantageously, the disclosed air filter and cable management assemblies allow for filtered cooling of stacked network communication systems while greatly simplifying the complexity of the filter and cable installation and maintenance. Other features and variations can be implemented, and related systems and methods can be utilized, as well.

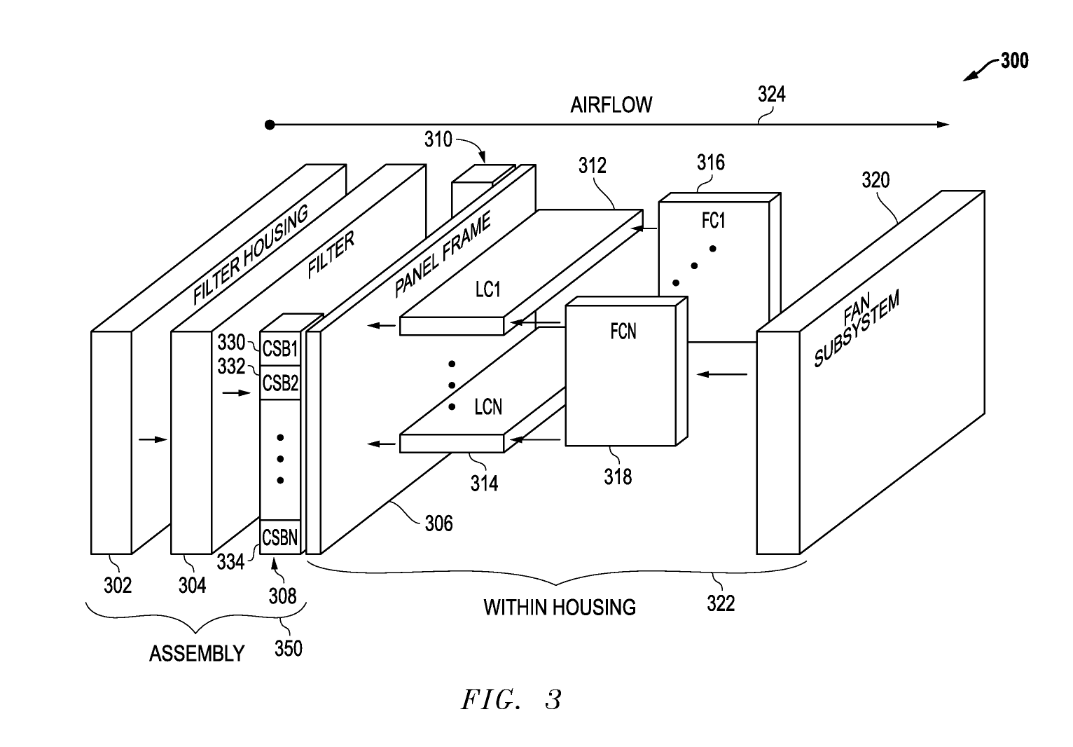

FIG. 3 is a block diagram of an embodiment 300 for a network communication system having an airflow and cable management assembly 350. The assembly 350 includes a filter housing 302 that covers and secures a filter 304. The filter housing 302 can be configured to allow airflow 324 to pass through the filter housing 302 to the filter 304 and ultimately to the connection panel frame 306. Cable support structures 308 and 310 are positioned with respect to the vertical edges of the connection panel frame 306. Each cable support structure 308/310 includes a number of cable support brackets (CSB1, CSB2 . . . CSBN) 330, 332 . . . 334 that are associated with the line cards (LC1 . . . LCN) 312 . . . 314 and that are utilized to support cables attached to the line cards (LC1 . . . LCN) 312 . . . 314. As described in more detail below, communication cables that are connected to the connection panel for each of the line cards (LC1 . . . LCN) 312 . . . 314 can be guided through the cable support brackets (CSB1, CSB2 . . . CSBN) 330, 332 . . . 334 that are located in the cable support structures 308 and 310. It is noted that the connection panels fro the line cards (LC1 . . . LCN) 312 . . . 314 can include connection ports for one or more types of communication cables and can include perforations or other techniques to allow air to flow through the connection panel and into the interior of the embodiment 300. Advantageously, the cable support brackets (CSB1, CSB2 . . . CSBN) 330, 332 . . . 334 provide a seal around the communication cables such that lateral airflow is restricted thereby forcing incoming air through the filter 304. It is further noted that embodiment 300 is only an example of how a network communication system can be configured and implemented. For example, the line cards (LC1 . . . LCN) 312 . . . 314 can be placed in vertical orientations, if desired, and a combination of horizontal and vertical orientations could be utilized, as well. Other variations could also be implemented as desired.

Looking further to embodiment 300, it is noted that embodiment 300 includes multiple communication systems that are implemented using line cards (LC1 . . . LCN) 312 . . . 314 and fabric cards (FC1 . . . FCN) 316 . . . 318. As described herein, each of the line cards (LC1 . . . LCN) 312 . . . 314 has a front connection panel and is attached to the connection panel frame 306 such that its connection panel is exposed to the front surface of the connection panel frame 306. These line cards (LC1 . . . LCN) 312 . . . 314 include circuitry and connection ports that provide interface connectivity to one or more communication cables. The fabric cards (FC1 . . . FCN) 316 . . . 318 are connected to the line cards (LC1 . . . LCN) 312 . . . 314. Further, the fabric cards (FC1 . . . FCN) 316 . . . 318 include circuitry that provides network switching functionality for handling network traffic between the line cards (LC1 . . . LCN) 312 . . . 314 and an external backplane that is typically connected the fabric cards (FC1 . . . FCN) 316 . . . 318. The fan subsystem 320 includes one or more fans that help to pull the airflow 324 through the embodiment 300. For embodiment 300, the air flow inlet is through the filter 304, and the airflow 324 is drawn by the fans which operate as an exhaust for the airflow 324. As indicated by bracket 322, the connection panel frame 306 can be a front portion of a housing that encloses the line cards (LC1 . . . LCN) 312 . . . 314, the fabric cards (FC1 . . . FCN) 316 . . . 318, the fan subsystem 320, and any other desired structure or circuitry that is utilized to implement the multiple network communication systems within embodiment 300.

It is again noted that the embodiment 300 is simply one example embodiment and other implementations could be made, as desired, that utilize a filter and cable management assembly as described herein. For example, embodiments can be configured to provide any desired form factor depending upon the desired end use. For example, a single line card could be used within the system where a 1U rack mount height implementation was desired. Other rack heights and form factors could also be implemented using any selected number of line cards and other components, as desired. As such, it should be recognized that additional and/or different components could be utilized, as desired, while still taking advantage of a common filter and cable management assembly for multiple network communication systems and related connection panels.

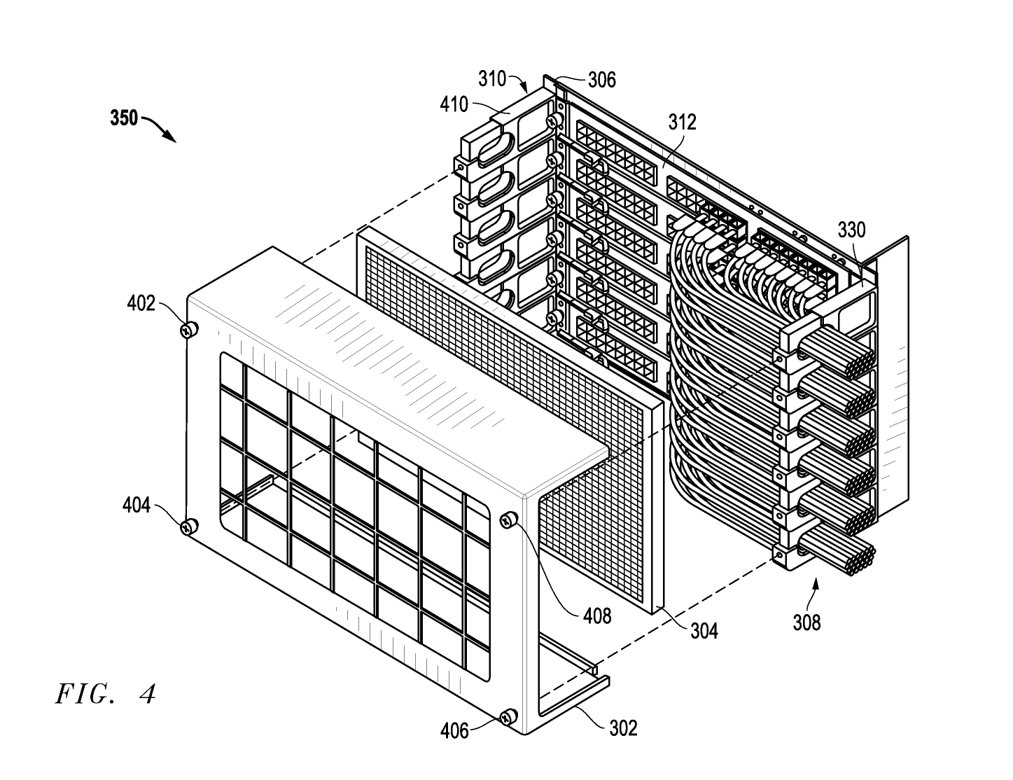

FIG. 4 is an expanded view diagram of a more detailed example embodiment for a filter and cable management assembly 350 coupled to the connection panel frame 306. For the embodiment depicted, the filter 304 includes a filter media enclosed within an outer filter frame, although other common filter configurations could also be utilized. The filter housing 302 includes an outer frame and an open interior with vertical and horizontal structures, such as wires, to retain the filter 304. The filter housing 302 can be shaped to fit over the filter 304 and around the cable support structures 308 and 310. Connectors 402, 404, 406, and 408 can be used to secure the filter housing 302 to the cable support structures 308 and 310. The cable support structures 308 and 310 in turn include a number of different cable support brackets, such as brackets 330 and 410. As described herein, the cable support brackets are associated with the connection panels for the line cards, such as line card 312, and are configured to support connected cables exiting the assembly 350. As further described herein, these cable support brackets provide a seal around the cables to restrict airflow through the brackets. For the embodiment depicted, there are six connection panels for six different line cards, and there are six cable support brackets within each of the cable support structures 308 and 310. The cables connected to the connection panels are then routed through the cable support brackets. It is further noted that cables can be routed through cable support structure 308 or through cable support structure 310; however, it is expected that half of the cable connections would use cable support structure 308 and the other half would use cable support structure 310 depending which is closest to the connection port.

It is noted that the filter media for the filter 304 can be implemented, as desired. In particular, the material and the material thickness for the filter media can be selected based upon various factors, such as particle filter size desired, amount of particulate removal desired, allowable airflow resistance, and/or other factors. One filter media that can be utilized is a one-half inch thick Quadrafoam porous filter having 25 PPI (pores per inch) available from Universal Air Filter. Such a filter media can remove greater than 80% of dust particles from the airflow while still providing relatively low airflow resistance, which improves airflow and reduces operational stress on the fan subsystem 320. The filter frame for the filter 304 can be sized and configured to match the filter housing 302 and to produce any desired shape for the filter 304, as desired. The filter housing 302 can be implemented, for example using a thin sheet of metal (e.g., 0.08 inch thick aluminum sheet) that has been shaped to fit around the cable support structures 308/310 and the filter 304. Variations could also be implemented, as desired, while still utilizing a common filter structure covering multiple connection panels, as described herein.

It is further noted that strips of air flow resistant material, such as strips of foam material, can be positioned on the back edges of the filter housing 302 that face and engage with the connection panel frame 306 and cable support structures 308/310. When the assembly is completed, these strips of air flow resistant material will form a seal that restricts and preferably eliminates air from seeping in at the connection seams for the filter housing 302. In this way, air flow is forced through the filter 304 rather than being allowed to bypass the filter 304 by entering through a connection seam for the housing 302.

FIG. 5 is a top view diagram of an embodiment 500 showing cable connections exiting through the cable support bracket 330. For the embodiment depicted, there are no cables connected and exiting through the cable support bracket 410, although it is understood that such connections could be made, if desired. As also depicted, the filter 304 is located in front of the connection panel for the line card 312. The filter housing 302 holds the filter 304 in place. As described above, the connectors 402 and 408 are utilized to secure the filter housing 302 to the cable support structures 308/310.

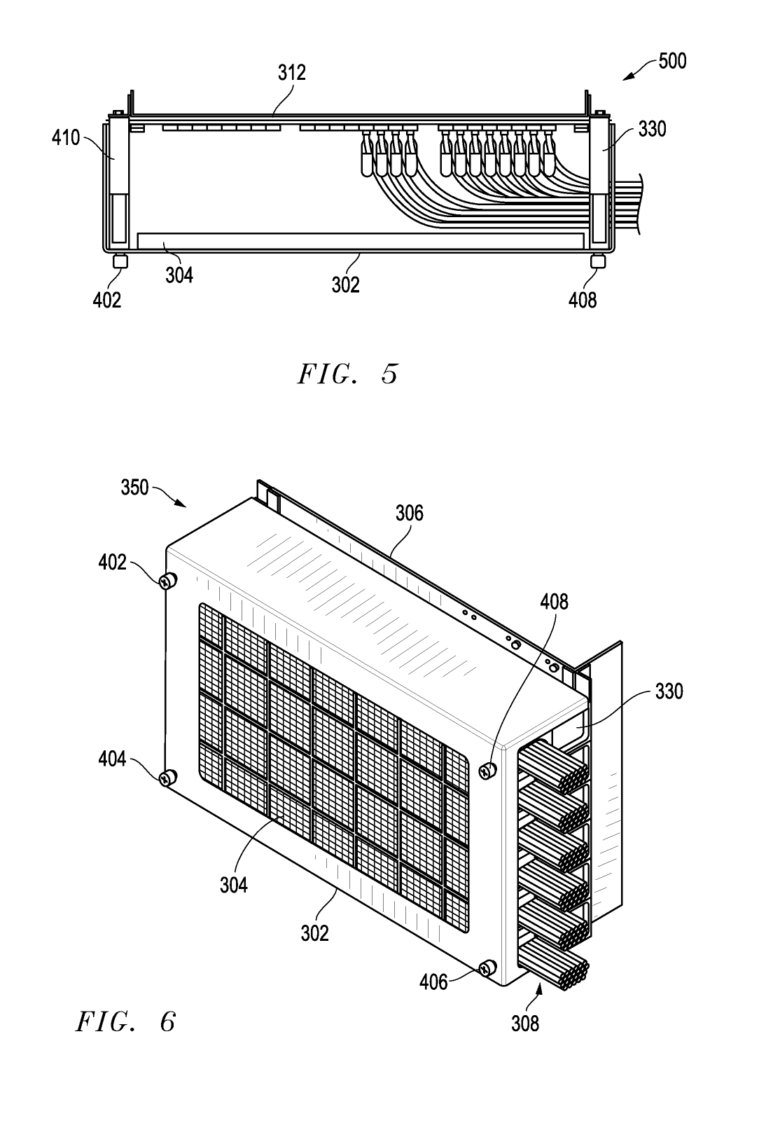

FIG. 6 is a collapsed view diagram showing an embodiment 600 for the closed filter and cable management assembly 350 coupled to the connection panel frame 306. As depicted, the filter 304 is held in place in front of the connection panels by the filter housing 302, and the filter housing 302 is secured in place by connectors 402, 404, 406, and 408. As also depicted, communication cables connected to the line cards exit through the cable support brackets, such as cable support bracket 330, within the cable support structure 308.

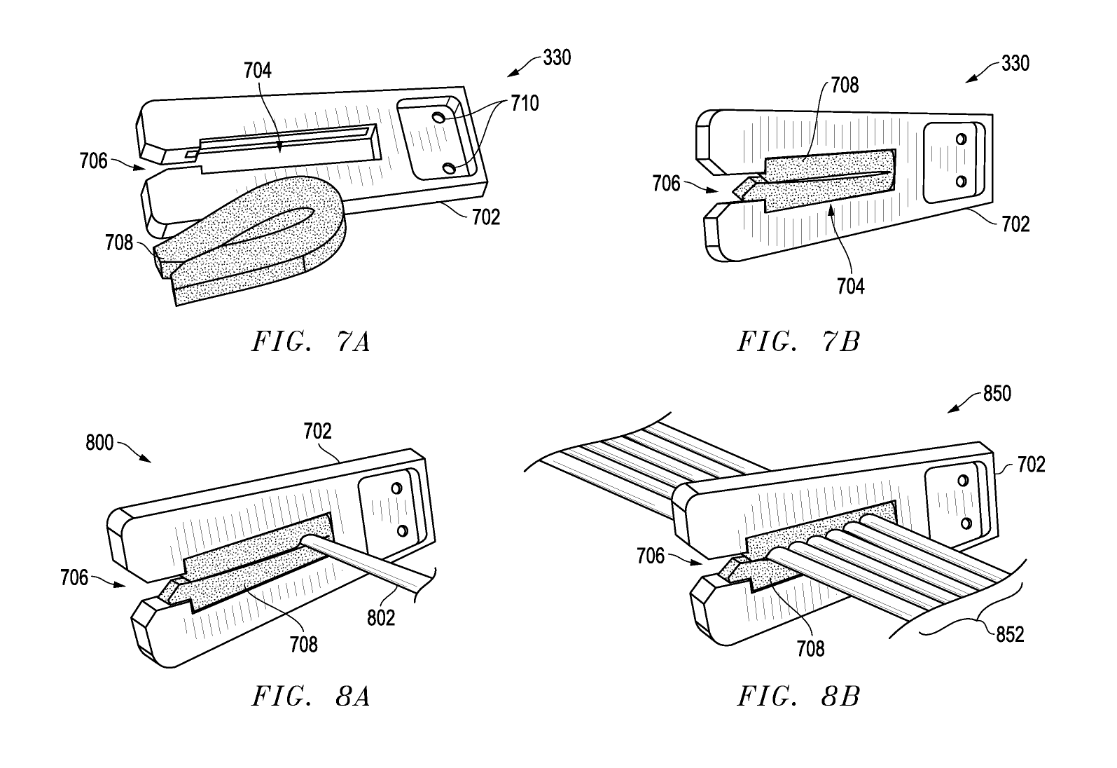

FIG. 7A is an exploded view diagram of an example embodiment for a cable support bracket 330. For the embodiment depicted, the cable support bracket 330 includes a support body 702 having a void 704 configured to receive a gasket 708. The support body 702 also includes a shaped opening 706 configured to facilitate the insertion of cables. The support body 702 can also have a connection mechanism to allow the support body 702 to be attached to the panel connection frame 306 or related structure. For example, holes 710 can be formed or otherwise provided within the support body 710 to allow for screws or push tabs to be used to attach the support body 702 to the panel frame 306. Other attachment mechanisms and structures can also be used, as desired, that allows for multiple support brackets to be positioned and secured to form the cable support structures 308 and 310.

FIG. 7B is a collapsed view of the cable support bracket 330 with the gasket 708 inserted and secured within the void 704. The resulting cable support bracket 330 is configured to receive cables into gasket 708 through opening 706. As described above, the back portion of the support body 702 can be secured as part of the cable support structure 308 using any desired attachment mechanism.

FIG. 8A is a diagram of an embodiment 800 where a single cable 802 has been inserted through the opening 706 for the support body 702 and into the gasket 708. As shown, the cable 802 is secured within the gasket 708, which forms a seal around the cable 802. This seal restricts external air from flowing through the cable support bracket.

FIG. 8B is a diagram of an embodiment 850 where multiple cables 852 have been inserted through the opening 706 for the support body 702 and into the gasket 708. As shown, the cables 852 are secured within the gasket 708, which forms a seal around the cables 852. This seal again restricts external air from flowing through the cable support bracket.

It is noted that the support body 702 and the gasket 708 can be formed and shaped using a variety of techniques while still achieving the desired result of restricting airflow through the cable support bracket 330 by forming a seal around cables inserted into the cable support bracket 330. While a completely airtight seal may be impractical to achieve, the gasket 708 will restrict airflow through the gasket such that relatively little air is allowed to bypass the filter 304 by flowing around any cables inserted into the gasket 708. Further, it is desirable that such an airflow restricting seal be maintained even when there are no cables connected and passing through the gasket 708. It is further noted that an adhesive and/or tape material can be used to secure the gasket 708 within the void 704 for the support body 102, if desired. For example, double-sided tape could be utilized to secure the gasket 708 within the void 704. Other materials and techniques could also be utilized, as desired.

The material and shape for the support body 702 can be selected based upon a variety of factors, such as strength, rigidity, ease of fabrication, and/or other factors. For example, the support body 702 can be formed using injected molded plastic, if desired. The support body 702 can also be formed using a metal material that is shaped through a stamping process. Other materials and techniques could also be utilized, as desired, to form the support body 702. Further, it is noted that the support body 702 can be implemented as a single piece or could be implemented as multiple pieces. Still further, it is noted that the opening 706 for the support body 702 can shaped to facilitate the insertion of cables, such as by being shaped to have a beveled opening 706, as shown in FIGS. 7A-B and 8A-B.

The material and structure for the gasket 708 can also be selected based upon a variety of factors, such as resilience, material memory, air seal quality, and/or other factors. For example, the gasket 708 can be formed using a flexible material that can be shaped and then secured within the void 704 for the support body 702. In addition, the gasket 708 can be formed in multiple pieces that are inserted within the void 704, or the gasket 708 can be formed as a single piece that is inserted into the void 704. For example, a single foam piece could be folded and inserted into void 704 as the gasket 708. Further, to provide for easier installation, a single die cut piece with a slit could also be inserted into void 704 for use as the gasket 708. Further, as with the opening 706 for the support body 702, the gasket 708 can be shaped to have an opening that facilitates the insertion of cables. Other variations and/or different structures could also be utilized, as desired, while still providing a gasket 708 that restricts lateral airflow through the cable support bracket 330.

Materials that can be used for the gasket 708 include injection molded plastics, Quadrafoam 45 PPI foam (very soft), Quadrafoam 80 PPI foam (soft), Poron polyurethane foam (firm), Neoprene/EPDM/SBR blended foam (very firm), and/or other desired materials. It is noted that Quadrafoam materials are available from Universal Air Filter, that Poron polyurethane foam materials are available from Rogers Corporation, that Neoprene is available from DuPont, that EPDM is ethylene propylene diene monomer (M-class) rubber, and that SBR is Styrene Butadiene rubber. It is noted that for optical fiber cables and larger cables, such as CAT6 communication cables, Poron polyurethane foam has been found to provide a good seal while having a relatively little small permanent compression or set of the material after cables are removed. Other materials could also be utilized, as desired.

Further modifications and alternative embodiments will be apparent to those skilled in the art in view of this description. It will be recognized, therefore, that the present invention is not limited by these example arrangements. Accordingly, this description is to be construed as illustrative only and is for the purpose of teaching those skilled in the art the manner of carrying out the invention. It is to be understood that the forms of the invention herein shown and described are to be taken as the example embodiments. Various changes may be made in the implementations and architectures described herein. For example, equivalent elements may be substituted for those illustrated and described herein, and certain features of the embodiments may be utilized independently of the use of other features, as would be apparent to one skilled in the art after having the benefit of this description.

What is claimed is:

1. A network communication system, comprising:
a connection panel frame having a front surface;
at least one communication system coupled to the connection panel frame, the communication system having a connection panel accessible from the front surface of the connection panel frame; and
a filter and cable management assembly coupled to the connection panel frame, the assembly comprising:
a cable support structure having at least one cable support bracket positioned along a vertical edge of the connection panel frame, the cable support bracket being configured to restrict airflow and to receive communication cables associated with the connection panel;
a filter positioned over the connection panel; and
a filter housing positioned over the filter to hold the filter in a secured relationship with respect to the cable support structure and the connection panel frame.

2. The network communication system of claim 1, wherein the at least one communication system comprises a plurality of communication systems coupled to the connection panel frame, each of the communication systems having a connection panel accessible from the front surface of the connection panel frame.

3. The network communication system of claim 2, wherein at least one cable support bracket is provided for each connection panel.

4. The network communication system of claim 2, wherein the cable support structure comprises a first cable support structure having a plurality of cable support brackets positioned along a first vertical edge of the connection panel frame and a second cable support structure having a plurality of cable support brackets positioned along a second vertical edge of the connection panel frame.

5. The network communication system of claim 4, wherein the communication systems comprise a plurality of communication line cards coupled to the connection panel frame and a plurality of fabric cards coupled to the communication line cards.

6. The network communication system of claim 5, further comprising a housing including the connection panel frame and holding the line cards and the fabric cards.

7. The network communication system of claim 6, further comprising a fan subsystem coupled within the housing.

8. The network communication system of claim 1, wherein the filter comprises a filter frame holding filter media.

9. The network communication system of claim 8, wherein the filter media comprises a porous filter material.

10. The network communication system of claim 1, wherein the cable support bracket comprises a support body having a void and a gasket positioned within the void.

11. The network communication system of claim 10, wherein the gasket comprises a foam material.

12. The network communication system of claim 11, wherein the foam material comprises polyurethane foam.

13. The network communication system of claim 10, wherein the gasket comprises multiple pieces.

14. The network communication system of claim 10, wherein the gasket comprises a single piece.

15. The network communication system of claim 10, wherein at least a portion of the gasket is folded to position the gasket within the void.

16. The network communication system of claim 1, wherein the cable support bracket is shaped to facilitate insertion of cables into the cable support bracket.

17. A filter and cable management assembly, comprising:
a cable support structure having at least one cable support bracket configured to be positioned along a first vertical edge of a connection panel frame for at least one communication system having a connection panel, the cable support bracket being configured to restrict airflow and to receive communication cables associated with the connection panel;
a filter; and
a filter housing positioned to hold the filter in a secured relationship with respect to the cable support structure and the connection panel frame.

18. The filter and cable management assembly of claim 17, wherein the cable support structure comprises a first cable support structure having a plurality of cable support brackets configured to be positioned along a first vertical edge of the connection panel frame and a second cable support structure having a plurality of cable support brackets configured to be positioned along a second vertical edge of the connection panel frame.

19. The filter and cable management assembly of claim 17, wherein the filter comprises a filter frame holding filter media.

20. The filter and cable management assembly of claim 19, wherein the filter media comprises a porous filter material.

21. The filter and cable management assembly of claim 17, wherein the cable support bracket comprises a support body having a void and a gasket positioned within the void.

22. The filter and cable management assembly of claim 21, wherein the gasket comprises a foam material.

23. The filter and cable management assembly of claim 22, wherein the foam material comprises polyurethane foam.

24. The filter and cable management assembly of claim 17, wherein the cable support bracket is shaped to facilitate insertion of cables into the cable support brackets.

25. A method for controlling airflow for a network communication system, comprising:
receiving airflow for a network communication system through a filter and cable management system, the filter and cable management system comprising:
a cable support structure having at least one cable support bracket positioned along a first vertical edge of a connection panel frame for at least one communication system having a connection panel, the cable support bracket restricting airflow and receiving communication cables associated with the connection panel;
a filter; and
a filter housing positioned to hold the filter in a secured relationship with respect to the cable support structure and the connection panel frame;
exhausting the airflow from the communication system.

26. The method of claim 25, wherein a plurality of communication systems are coupled to the connection panel frame, and wherein each of the communication systems has a connection panel accessible from the front surface of the connection panel frame.

27. The method of claim 26, wherein the cable support structure comprises a first cable support structure having a plurality of cable support brackets positioned along a first vertical edge of the connection panel frame and a second cable support structure having a plurality of cable support brackets positioned along a second vertical edge of the connection panel frame.

28. The method of claim 27, wherein the communication systems comprise a plurality of communication line cards coupled to the connection panel frame and a plurality of fabric cards coupled to the communication line cards.

29. The method of claim 25, wherein the exhausting step is performed using a fan subsystem.

30. The method of claim 25, wherein the cable support bracket comprises a support body having a void and a gasket positioned within the void.
